(19) United States
(12) Patent Application Publication
(10) Pub. No.: US 2012/0037204 A1
(43) Pub. Date: Feb. 16, 2012

(54) SOLAR SYSTEM AND SOLAR TRACKING METHOD FOR SOLAR SYSTEM

(76) Inventor: Tien-Hsiang SUN, Hsinchu City (TW)

(21) Appl. No.: 12/854,002

(22) Filed: Aug. 10, 2010

(51) Int. Cl. H01L 31/052

(52) U.S. Cl. 136/246

(57) ABSTRACT

The invention provides a solar system and a solar tracking method for a solar system. An exemplary embodiment of a solar system includes a substrate comprising a solar cell array disposed thereon. An optical element array is disposed over the substrate to concentrate sunbeams onto the solar cell array. An actuator is affixed to the substrate, wherein the actuator shifts the substrate along an axis direction. A feedback module is electrically coupled to the substrate and the actuator, wherein the feedback module respectively measures a first, a second and a third voltage of the solar cell array corresponding to the first, the second and the third position, and finds a maximum voltage among the first, second and third voltages, thereby defining a maximum feedback position at which the maximum voltage occurs.

### BACKGROUND OF THE INVENTION

1. Field of the Invention

The present invention relates to a solar system and a solar tracking method for a solar system, and in particular, to a solar system with a feedback mechanism and a solar tracking method a solar system.

2. Description of the Related Art

A solar tracker is a device for orienting a daylighting reflector, solar photovoltaic panel or concentrating solar reflector or lens toward the sun. The suds position in the sky varies both with the seasons and time of day as the sun moves across the sky. Solar powered equipment works best when facing directly towards the sun or being disposed as close as possible to the sun. Thus, a solar tracker, which increases system complexity of solar powered equipment, can increase the effectiveness of solar powered equipment, as compared to if solar powered equipment remained in a fixed position. The conventional solar trackers comprise active trackers and passive trackers. Active solar trackers use motors and gear trains to direct the tracker toward a solar direction according to a controller. Maintenance of active solar trackers, however, is troublesome due to alignment deviations caused by nature. Passive solar trackers use a low boiling point compressed gas fluid that is driven to one side or another (by solar heat creating gas pressure), to cause the tracker to move in response to an imbalance. Passive solar trackers, however, do not track the sun very accurately.

Thus, a novel solar system and a solar tracking method are desired.

### BRIEF SUMMARY OF INVENTION

A solar system and a solar tracking method for a solar system having a solar cell array on a substrate are provided. An exemplary embodiment of a solar system comprises a substrate comprising a solar cell array disposed thereon. An optical element array is disposed over the substrate to concentrate sunbeams onto the solar cell array. An actuator is affixed to the substrate, wherein the actuator shifts the substrate along an axis direction. A feedback module electrically is coupled to the substrate and the actuator, wherein the feedback module respectively measures a first, a second and a third voltage of the solar cell array corresponding to the first, the second and the third position, and finds a maximum voltage among the first, second and third voltages, thereby defining a maximum feedback position at witch the maximum voltage occurs.

An exemplary embodiment of a solar tracking method for a solar system having a solar cell array on a substrate is provided and comprises the steps of: (a) measuring a first voltage of the solar cell array at a first position on the substrate; (b) shifting the substrate by a first distance positively along an axis direction; (c) measuring a second voltage of the solar cell array at a second position on the substrate; (d) shifting the substrate by a second distance negatively along the axis direction; (e) measuring a third voltage of the solar cell array at a third position on the substrate; (f) finding a maximum voltage among the first, second and third voltages; (g) defining a maximum feedback position at witch the maximum voltage occurs; and (h) shifting the substrate to the maximum feedback position.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a top view of one exemplary embodiment of a solar system of the invention.

FIG. 2 is a cross section view taken along line A-A′ of FIG. 1.

FIG. 3a is cross section of one exemplary embodiment of a solar system showing the sunbeams directly concentrated onto the solar cell array.

FIGS. 3b and 3c are feedback voltage diagrams along the X-axis and Y-axis directions of the solar cell array of FIG. 3a.

FIG. 3d is top view of a portion of the substrate comprising a solar cell showing the concentrated sunbeam positions of FIG. 3a.

FIGS. 4a to 4h show one exemplary embodiment of a solar tracking method for a solar system with a feedback mechanism.

FIGS. 5a and 5b are feedback voltage diagrams along the X-axis and Y-axis directions of the solar cell array of FIGS. 4a to 4h.

FIG. 6 is top view of a portion of the substrate comprising a solar cell showing the concentrated sunbeam positions of FIGS. 4a to 4h.

FIG. 7 is a flow chart showing the feedback mechanism of the feedback module of one exemplary embodiment of the solar system obtaining the maximum feedback voltage of the solar cell array.

### DETAILED DESCRIPTION OF INVENTION

The following description is of a mode for carrying out the invention. This description is made for the purpose of illustrating the general principles of the invention and should not be taken in a limiting sense. The scope of the invention is best determined by reference to the appended claims. Wherever possible, the same reference numbers are used in the drawings and the descriptions to refer the same or like parts.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated and not drawn to scale for illustrative purposes. The dimensions and the relative dimensions do not correspond to actual dimensions to practice the invention.

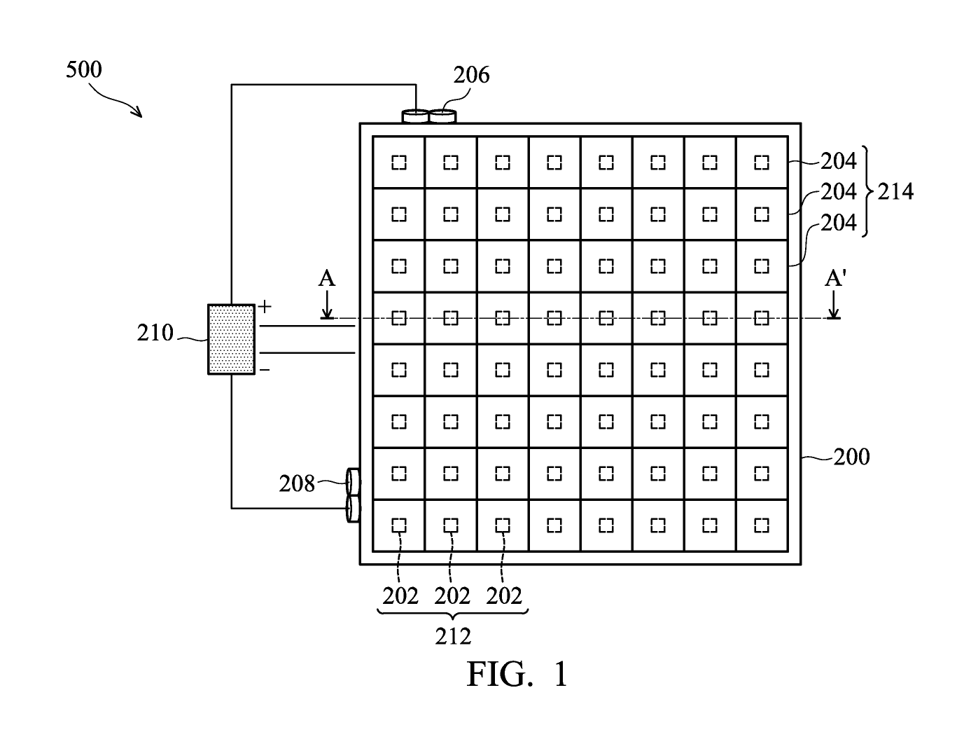

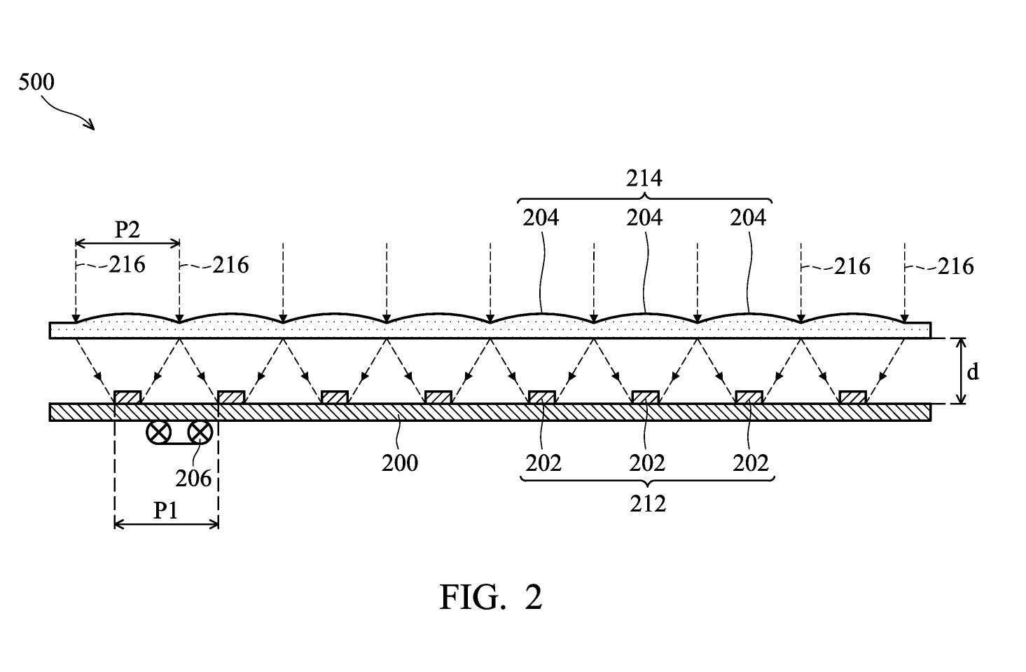

FIG. 1 is a top view of one exemplary embodiment of a solar system 500 of the invention. FIG. 2 is a cross section view taken along line A-A′ of FIG. 1. The solar system 500 such as a concentrating photovoltaic (CPV) system 500 may comprise a substrate 200 comprising a solar cell array 212 comprising a plurality of solar cells 202 disposed thereon. In one embodiment, the substrate 200, serving as a carrier and/or a heat dissipation element for the solar cell array 212, may comprise dielectric materials such silicon, ceramic or the like, or metal materials such as Al or the like. In one embodiment, the solar cells 202 work with a semiconductor that has been doped to form two different regions separated by a p-n junction. An optical element array 214 comprising a plurality of optical elements 204 is disposed over the substrate 200 for guiding sunbeams 216 to the solar cell array 212. In one embodiment, a vertical distance d between the solar cell array 212 and the optical element array 214 is fixed. In one embodiment, the optical elements 204 may comprise lenses made from glass or acryl. Alternatively, the optical elements 204 may comprise reflectors. As shown in FIGS. 1a and 1b, in one embodiment, the solar cells 202 of the solar cell array 212 may have a first pitch P1, and the optical elements 204 of the optical element array 214 may have a second pitch P2 which is the same as the first pitch P1. A first actuator 206 and a second actuator 208, which are affixed to the substrate 200, to respectively shift the substrate 200 along a first axis direction 220 and a second axis direction 222 to change a relatively position between the solar cell array 212 on the substrate 200 and the optical element array 214. A feedback module 210 is electrically coupled to the substrate 200, the first actuator 206 and the second actuator 208 for continuous solar tracking. For example, the feedback module 210 drives the first actuator 206 or the second actuator 208 to shift the substrate 200 along an axis direction and measures a first, a second and a third feedback voltage of the solar cell array 212 when the sunbeams 216 are concentrated on a first, a second and a third position on the substrate 200 by the optical element array 214. Also, the feedback module 210 finds a maximum feedback voltage among the first, second and third feedback voltages of the solar cell array 212 along the axis direction, thereby defining a maximum feedback position on the substrate 200 at which the maximum feedback voltage occurs, wherein the substrate is shifted 200 until the sunbeams 216 are concentrated on the maximum feedback position on the substrate 200 at which the sunbeams 216 are directly concentrated onto the solar cell array 212, wherein the first position is between the second and third positions.

In one embodiment, the feedback module 210 may be integrated with the substrate 200 to reduce volume of the solar system 500. In one embodiment, the first axis direction 220 and the second axis direction 222 which is different from the first axis direction 220 may be orthogonal. In this embodiment, the first axis direction 220 is an X-axis direction 220 and the second axis direction 222 is a Y-axis direction 222, so that the first actuator 206 serves as an X-axis actuator 206 and the second actuator 208 serves as Y-axis actuator 208.

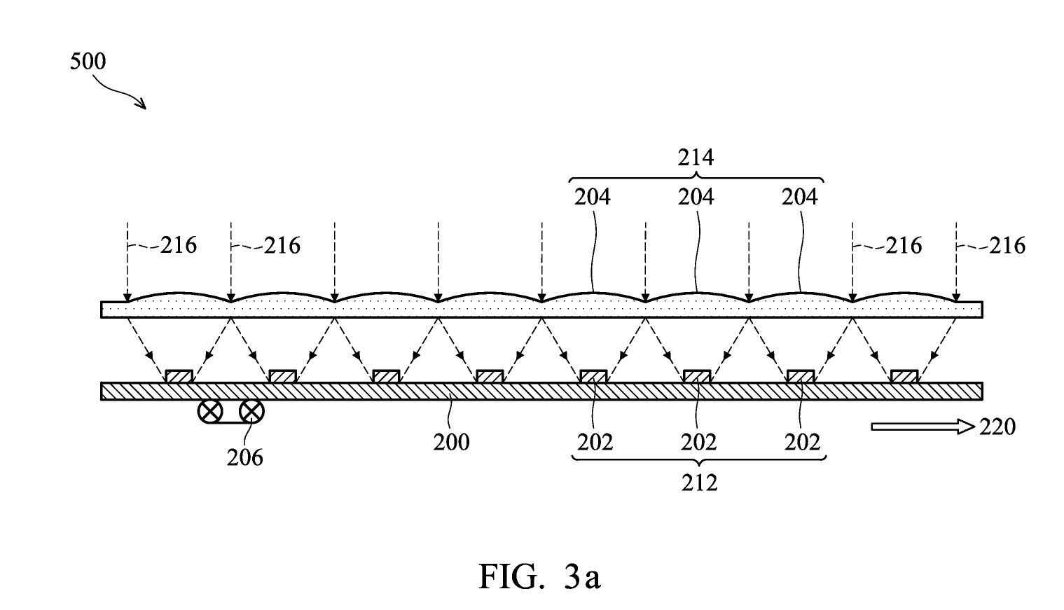

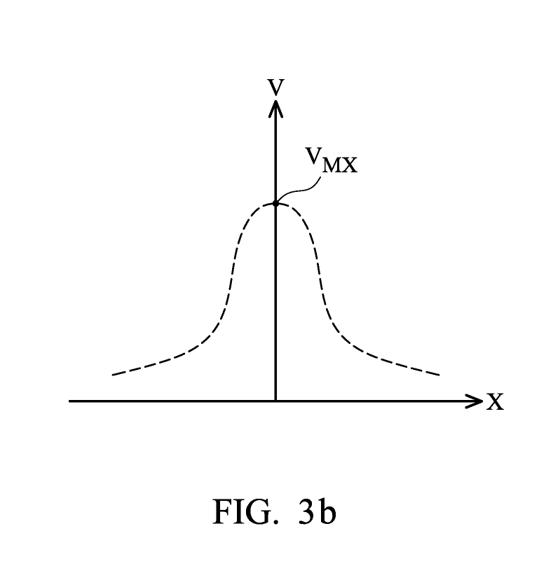

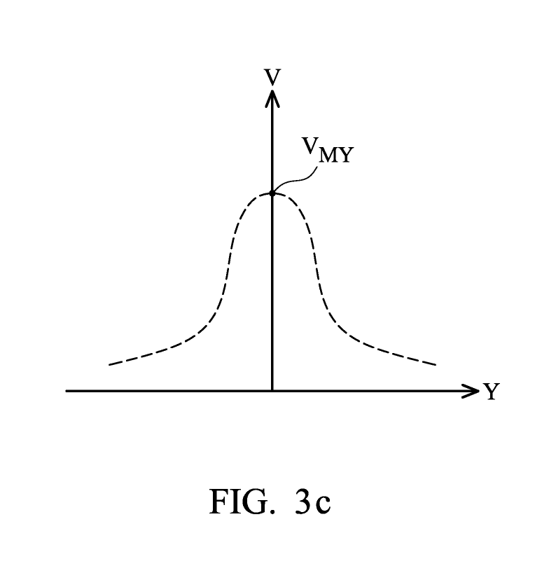

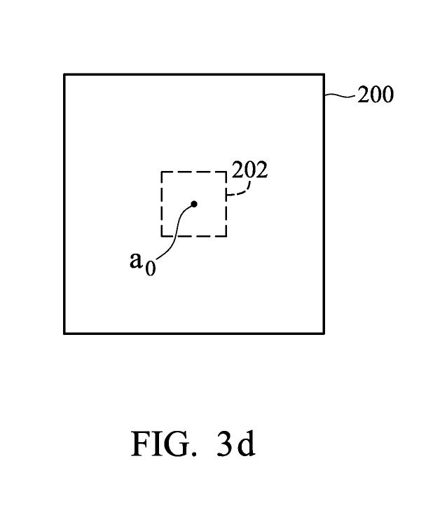

FIG. 3a is cross section along a first axis direction 220 of one exemplary embodiment of a solar system 500 showing the sunbeams 216 directly concentrated onto the solar cell array 212. FIGS. 3b and 3c are feedback voltage diagrams along the X-axis and Y-axis directions of the solar cell array 212 of FIG. 3a. FIG. 3d is top view of a portion of the substrate comprising a solar cell 202 showing the concentrated sunbeam positions of FIG. 3a. As shown in FIGS. 3a to 3c, when the sunbeams 216 are directly concentrated onto the solar cells 202 of the solar cell array 212 by the optical element array 214, the sunbeams 216 are concentrated on a position a₀ which is directly on the solar cell 202. At this time, the feedback module 210 measures a maximum feedback voltage of the solar cell array 212 comprising a maximum X-axis feedback voltage V_{MX} and a maximum Y-axis feedback voltage V_{MY} along the X-axis and Y-axis directions.

The following description describes how the solar system 500 uses the feedback module 210 as shown in FIGS. 1a and 1b to determine the shifting direction and distance between the substrate 200 and the optical element array 214 for solar tracking.

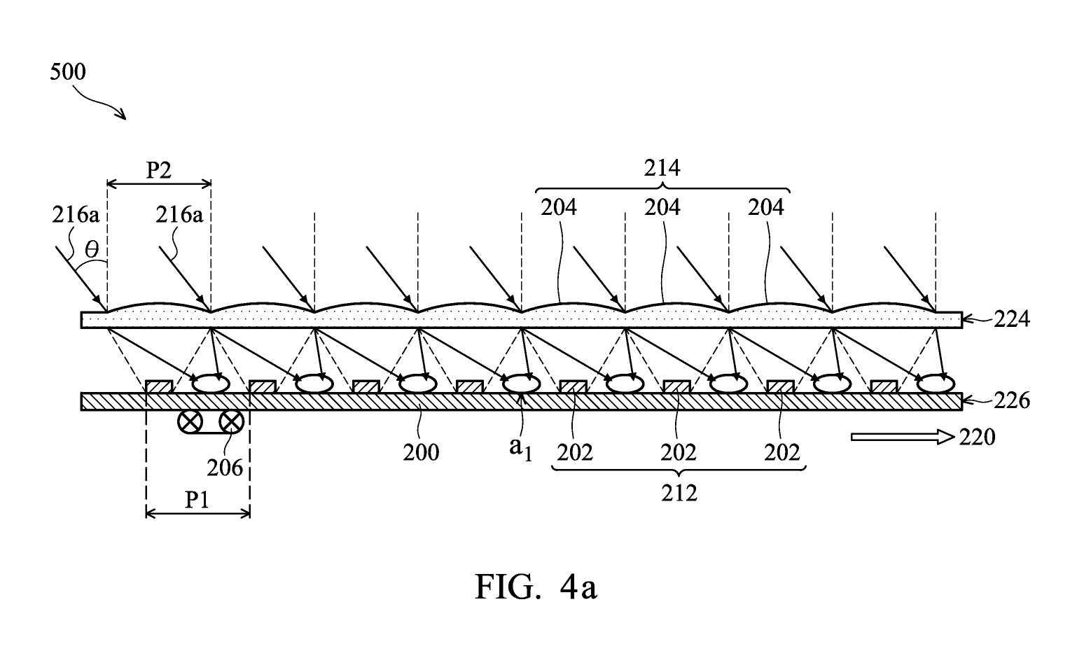

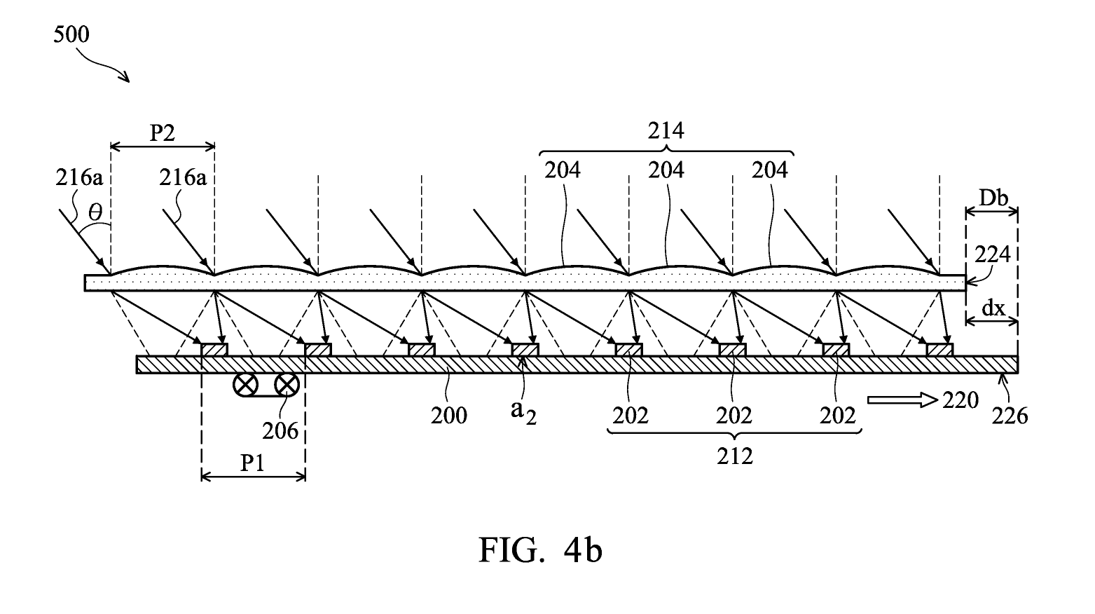

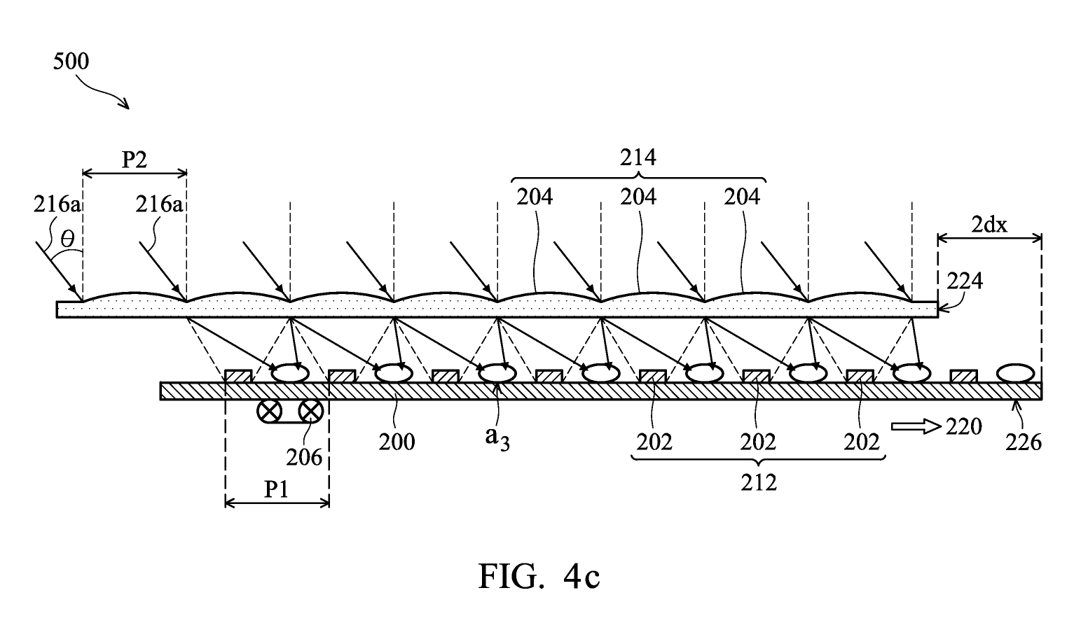

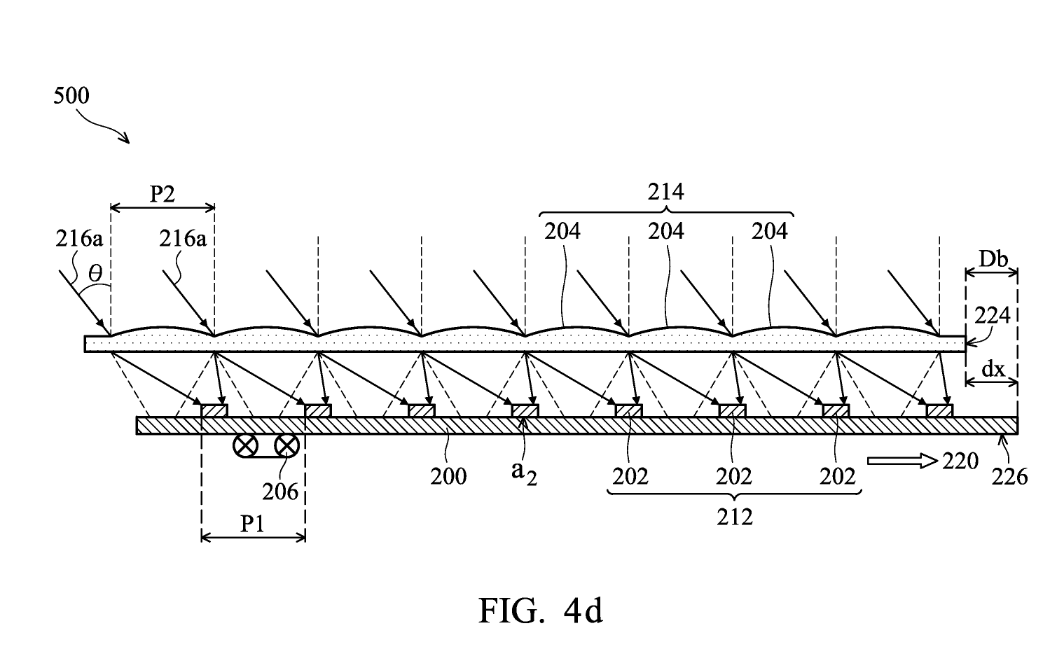

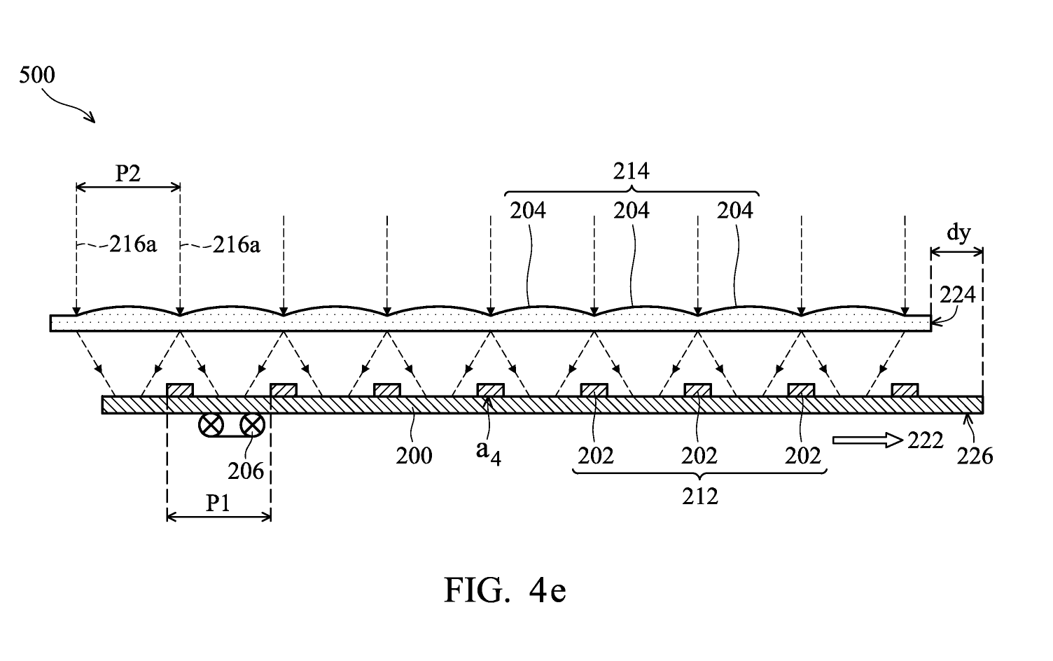

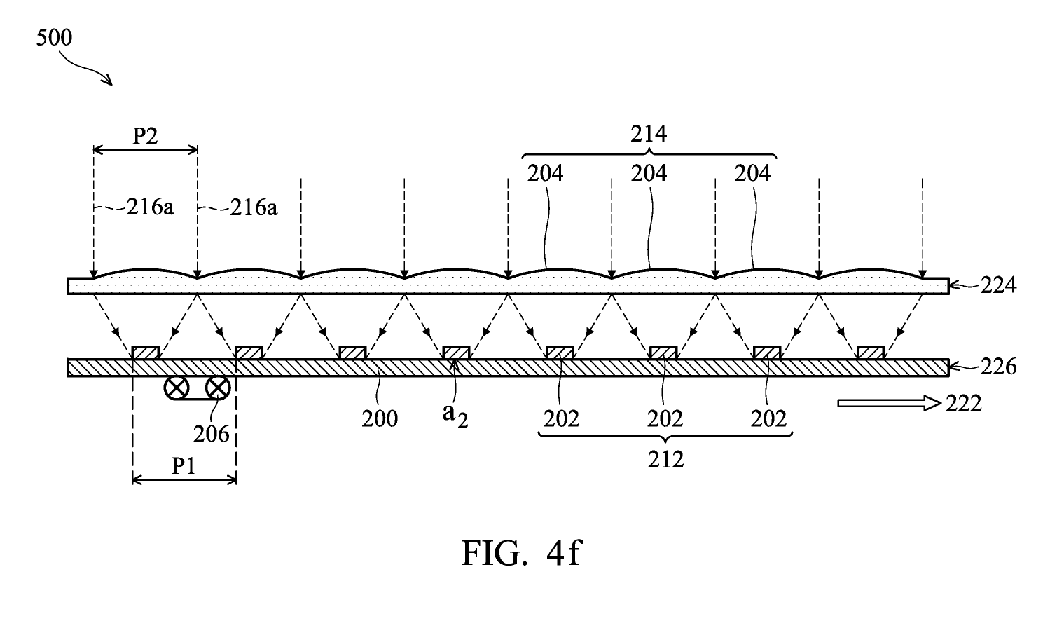

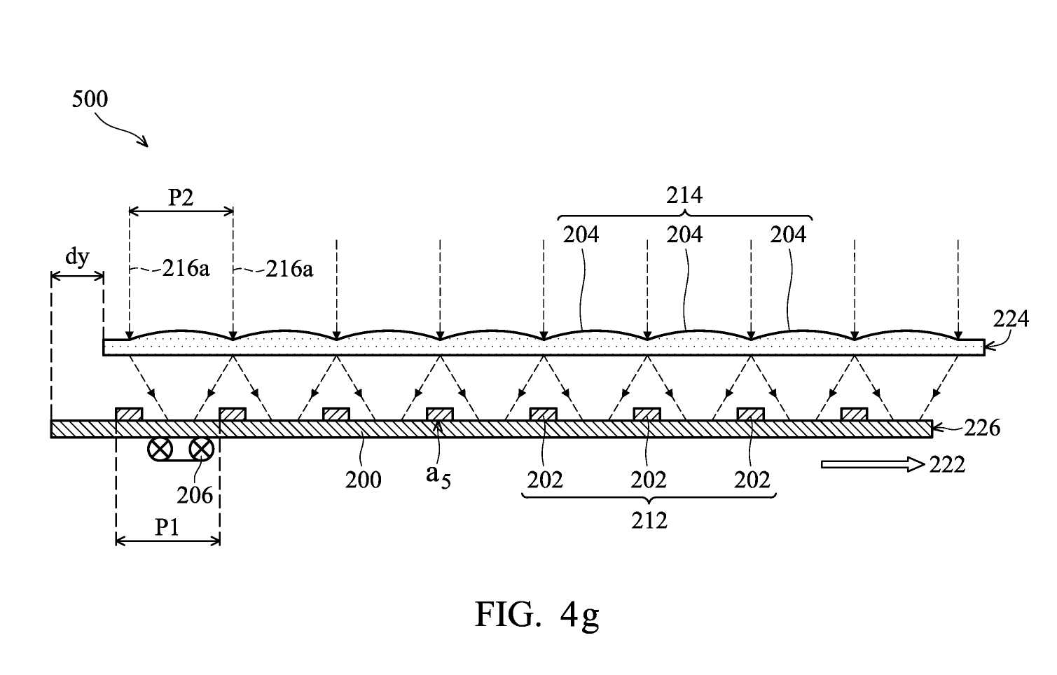

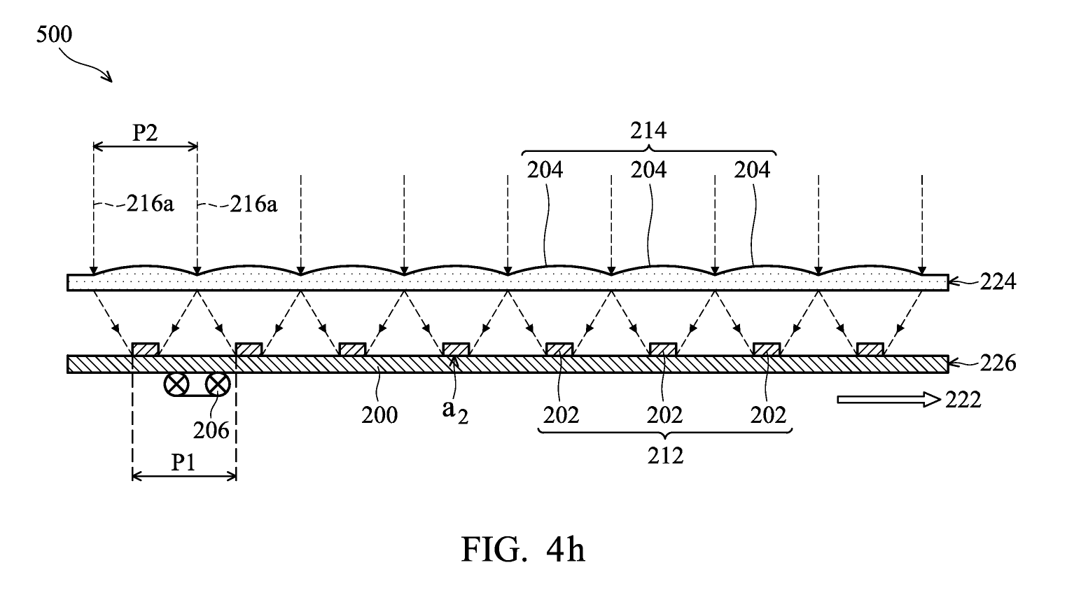

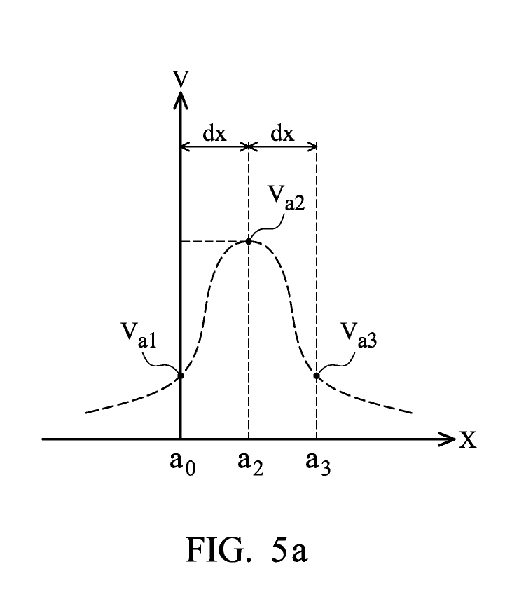

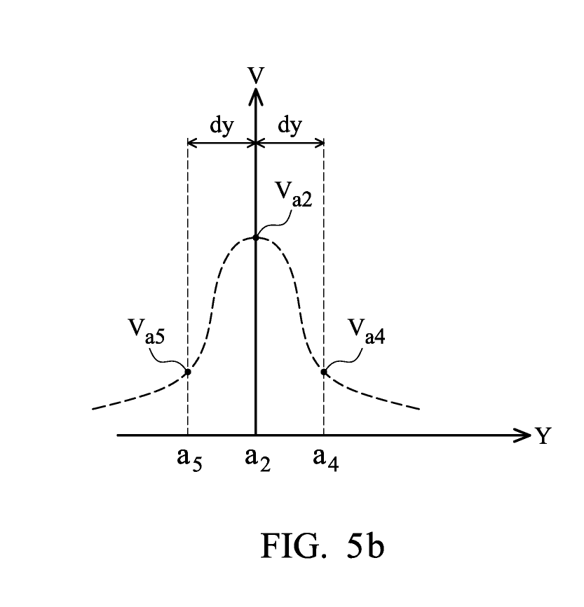

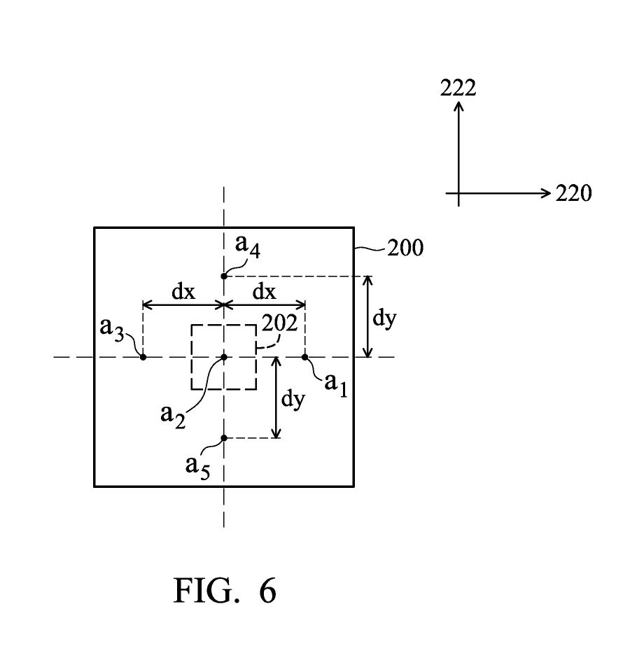

FIGS. 4a to 4h show one exemplary embodiment of a solar tracking method for a solar system 500 with a feedback mechanism. FIGS. 5a and 5b are feedback voltage diagrams along the X-axis and Y-axis directions of the solar cell array of FIGS. 4a to 4h. FIG. 6 is top view of a portion of the substrate comprising a solar cell showing the concentrated sunbeam positions of FIGS. 4a to 4h. The solar tracking method using a solar system 500 with a feedback mechanism may first start by finding a maximum X-axis feedback voltage V_{MX} of the solar cell array 212, and then finding a maximum Y-axis feedback voltage V_{MY} of the solar cell array 212, so that the maximum feedback voltage of the solar cell array 212 between the maximum X-axis feedback voltage V_{MX} and the maximum Y-axis feedback voltage V_{MY} is defined. Also, the maximum feedback position on the substrate 200 at which the maximum feedback voltage occurs is defined. Alternatively, the sequence of finding the maximum X-axis feedback voltage V_{MX} and the maximum Y-axis feedback voltage V_{MY} may be exchanged and is not limited thereto.

FIGS. 4a to 4d, 5a and 6 illustrate a solar tracking method performing along a first axis direction 220 such as an X-axis direction 220 to find the maximum X-axis feedback voltage V_{MX} by using the feedback module 210. Referring to FIGS. 4a and 6, when the sunbeams 216a are incident onto the optical element array 214 with an incident angle θ, the sunbeams 216a are concentrated onto a positional on the substrate 200. At this time, the feedback module 210 measures a feedback voltage Va1 of the solar cell array 212 along a first axis direction 220 such as an X-axis direction 220. Next, referring to FIGS. 4b and 6, the substrate 200 is shifted by a unit distance dx positively along a first axis direction 220 such as an X-axis direction 220 by the feedback module 210, so that the sunbeams 216a are concentrated onto a position a2 on the substrate 200. At this time, the feedback module 210 measures a feedback voltage Va2 of the solar cell array 212 as show in FIG. 5a. In one embodiment, the unit distance dx may be smaller than or equal to the first pitch P1 of the solar cell array 212. Also, the unit distance dx may be smaller or equal to the second pitch P2 of the optical element array 214.

As shown in FIG. 5a, because the measured feedback voltage Va1 is smaller than the feedback voltage Va2, the feedback module 210 performs a step of shifting the substrate 200 by the unit distance dx positively along the first axis direction 220 such as an X-axis direction 220 as shown in FIGS. 4c and 6 and a step of measuring a feedback voltage Va3 of the solar cell array 212 as shown in FIG. 5a when the sunbeams are concentrated onto a position a3 on the substrate 200 by the optical element array 214, wherein a distance between the positions a1 and a3 is larger than that between the positions a1 and a2. As shown in FIG. 5a, the measured feedback voltage Va2 is larger than the feedback voltage Va3.

As shown in FIG. 5a, because the feedback voltage Va2 is larger than the feedback voltage Va3, the feedback module 210 performs a step of shifting the substrate 200 negatively along the first axis direction 220 such as an X-axis direction 220 so that the sunbeams 216a are concentrated onto a position a2 of the substrate 200 as shown in FIGS. 4d and 6. At this time, the feedback voltage Va2 as shown in FIG. 5a can be defined as the maximum X-axis feedback voltage V_{MX} among the feedback voltages Va1, Va2 and Va3.

Before the substrate 200 is shifted as shown in FIGS. 4b, 4c and 4d, the feedback module 210 may check the a horizontal distance Db between an edge 226 of the substrate 200 and a edge 226 of the optical element array 214 adjacent and parallel to the edge 226, wherein the horizontal distance Db satisfies the boundary condition of Db≦P1 and Db≦P2. When the horizontal distance Db does not satisfy the boundary condition, the substrate 200 is not shifted along a first axis direction 220. The boundary condition of the horizontal distance Db limits the horizontal distance between the edge 226 of the substrate 200 and the edge 226 of the optical element array 214 to insure that sunbeams are concentrated on all of the solar cells of the solar cell array 212.

Alternatively, when the feedback voltage Va2 is the same as or smaller than the feedback voltage Va3, the feedback module 210 may perform the step of shifting the substrate 200 by the unit distance dx negatively along the first axis direction 220 such as an X-axis direction 220 and measure a feedback voltage of the solar cell array 212 until the maximum X-axis feedback voltage V_{MX} among the previously measured feedback voltages is found.

After finding the maximum X-axis feedback voltage V_{MX}, the feedback module 210 performs the steps of changing the relative position between the substrate 200 and the optical element array 214 for solar tracking along the second axis direction 222 such as a Y-axis direction 222 as shown in FIGS. 4e to 4h, 5b and 6.

Next, referring to FIGS. 4e and 6, the feedback module 210 performs a step of shifting the substrate 200 by an unit distance dy positively along the second axis direction 222 such as a Y-axis direction 222 and a step of measuring a feedback voltage Va4 of the solar cell array 212 as shown in FIG. 5b when the sunbeams are concentrated onto a position a4 on the substrate 200 by the optical element array 214. In one embodiment, the magnitude of the unit distance dy is the same as the unit distance dx.

As shown in FIG. 5b, because the measured feedback voltage Va2 is larger than the feedback voltage Va4, the feedback module 210 then performs a step of shifting the substrate 200 back to the position a2 by a unit distance dy negatively along the second axis direction 222 such as a Y-axis direction 222 as shown in FIGS. 4f and 6.

Next, referring to FIGS. 4g and 6, the feedback module 210 performs a step of shifting the substrate 200 by an unit distance dy negatively along the second axis direction 222 such as a Y-axis direction 222 to measure a feedback voltage Va5 of the solar cell array 212 as shown in FIG. 5b when the sunbeams are concentrated onto a position a5 on the substrate 200 by the optical element array 214. As shown in FIG. 5b, because the measured feedback voltage Va2 is larger than the feedback voltage Va4, the feedback module 210 then performs a step of shifting the substrate 200 back to the position a2 by a unit distance dy positively along the second axis direction 222 such as a Y-axis direction 222 as shown in FIGS. 4h and 6. At this time, the feedback voltage Va2 as shown in FIG. 5b can also be defined as the maximum Y-axis feedback voltage V_{MY} among the feedback voltages Va2, Va4 and Va5.

Before the substrate 200 is shifted as shown in FIGS. 4e, 4f, 4g and 4h, the feedback module 210 may check the a horizontal distance Db between an edge 226 of the substrate 200 and a edge 226 of the optical element array 214 adjacent and parallel to the edge 226, wherein the horizontal distance Db satisfies the boundary condition of Db≦P1 and Db≦P2. When the horizontal distance Db does not satisfy the boundary condition, the substrate 200 is not shifted along a second axis direction 222.

Alternatively, when the feedback voltage Va2 is the same or smaller than the feedback voltages Va3 or Va5, the feedback module 210 may perform the step of shifting the substrate 200 by the unit distance dy positively or negatively along the second axis direction 222 such as a Y-axis direction 222 and a step of measuring a feedback voltage of the solar cell array 212 until the maximum Y-axis feedback voltage V_{MY} among the previously measured feedback voltages is found.

Because the feedback voltage Va2 is defined as both the maximum X-axis feedback voltage V_{MX} and the maximum Y-axis feedback voltage V_{MY}, the feedback voltage Va2 is defined as the maximum feedback voltage of the solar cell array 212. After the aforementioned steps are completed, the sunbeams 216a are directly concentrated onto the solar cell array 212. Alternatively, when the maximum X-axis feedback voltage V_{MX} and the maximum Y-axis feedback voltage V_{MY} are different, the larger one can be defined as the maximum feedback voltage. Therefore, the position a2 is defined as a maximum feedback position on the substrate 200.

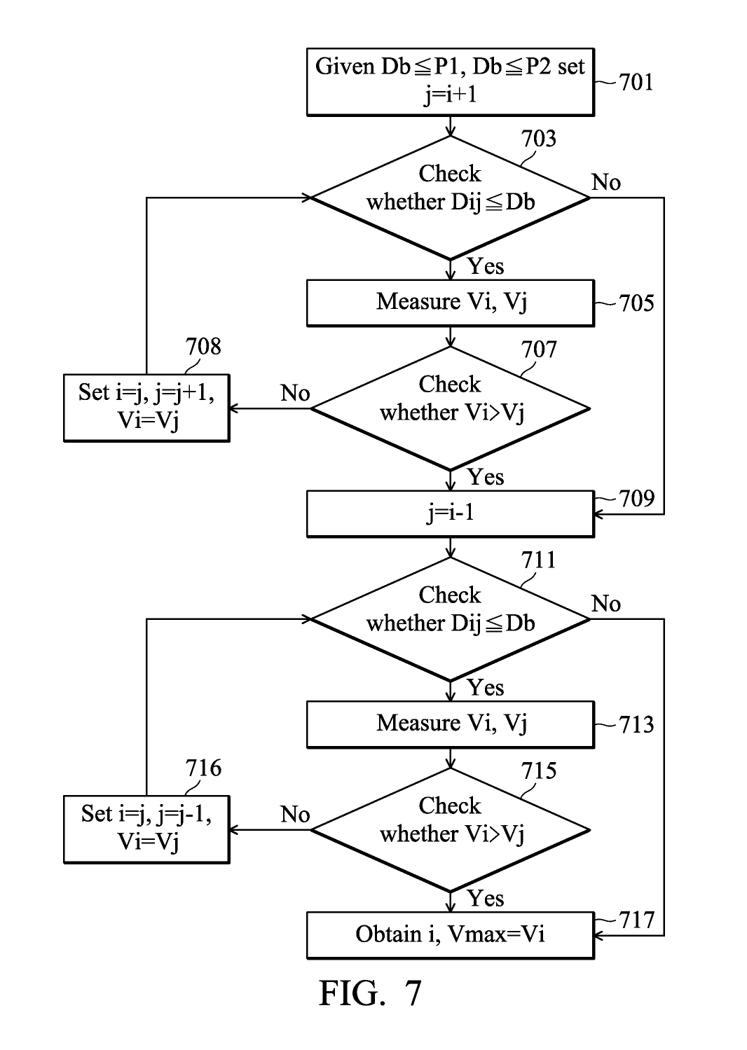

FIG. 7 is a flow chart showing the feedback mechanism of the feedback module 210 of one exemplary embodiment of the solar system 500 obtaining the maximum feedback voltage of the solar cell array 212 (as shown in FIGS. 1 and 2). Firstly, the feedback module 210 sets two positions, a position i and a position j, on the substrate 200 for the sunbeams to be concentrated thereon, wherein i and j are axis coordinate values, i is an integer number and j=i+1 (step 701). Also, a boundary condition of the feedback module 210 is Db≦P1 and Db≦P2, wherein Db is the horizontal distance between the adjacent edges of the substrate 200 and the optical element array 214, P1 is a pitch of the solar cell array 212, and P2 is a pitch of the optical element array 214 (step 701). Next, the feedback module 210 checks whether a distance Dij between the position i and the position j satisfies Dij≦Db (step 703). When Dij≦Db, the feedback module 210 measures a feedback voltage V1 at the position i and a feedback voltage Vj at the position j (step 705). When Dij does not satisfy Dij≦Db, the feedback module 210 sets j to satisfy j=i−1 (step 709). After the feedback module 210 performs step 705, the feedback module 210a checks whether Vi and Vj satisfy Vi>Vj (step 707). When Vi>Vj, the feedback module 210 sets j to satisfy j=i−1 (step 709). When Vi and Vj do not satisfy Vi>Vj, the feedback module 210 sets i=j, j=j+1 and Vi=Vj (step 708) and then performs step 703 again until the feedback module 210 sets j to satisfy j=i−1 (step 709).

Additionally, after performing step 709, the feedback module 210 checks whether a distance Dij between the position i and the position j satisfy Dij≦Db (step 711). When Dij≦Db, the feedback module 210 measures a feedback voltage V1 of the position i and a feedback voltage Vj at the position j (step 713). When Dij does not satisfy Dij≦Db, the feedback module 210 determines that the position i is the maximum feedback position, and the feedback voltage V1 is the maximum feedback voltage (step 717). After performing step 713, the feedback module 210 determines whether Vi and Vj satisfy Vi>Vj (step 715). When Vi>Vj, the feedback module 210 determines that the position i is the maximum feedback position, and the feedback voltage V1 is the maximum feedback voltage (step 717). When Vi and Vj do not satisfy Vi>Vj, the feedback module 210 sets i=j, j=j−1 and Vi=Vj (step 716) and then performs step 711 again until the feedback module 210 determines that the position i is the maximum feedback position, and the feedback voltage V1 is the maximum feedback voltage (step 717).

One exemplary embodiment of a solar system has a feedback mechanism is provided for continuous solar tracking. When the sunbeams from the sun move with time, one exemplary embodiment of the solar system may shift relative positions between a substrate and a optical element array thereof (for example, shifting the substrate) according to the feedback voltage from a solar cell array disposed on the substrate until the sunbeams are directly concentrated onto the solar cell array. One exemplary embodiment of a solar system has the following advantages. The optical elements may comprise lenses or reflectors without limiting the size thereof. The feedback module may be integrated with the substrate to reduce the volume of the solar system. Therefore, one exemplary embodiment of a solar system may have lower maintenance costs than that of conventional solar systems using active solar trackers and higher accuracy for solar tracking than that of conventional solar systems using passive solar trackers. One exemplary embodiment of a solar system without the conventional solar trackers can be especially applied in small-sized concentrating photovoltaic (CPV) systems.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar system, comprising:
a substrate comprising a solar cell array disposed thereon;
an optical element array disposed over the substrate to concentrate sunbeams onto the solar cell array;
an actuator affixed to the substrate, wherein the actuator shifts the substrate along an axis direction; and
an feedback module electrically coupled to the substrate and the actuator, wherein the feedback module respectively measures a first, a second and a third voltage of the solar cell array corresponding to the first, the second and the third position, and finds a maximum voltage among the first, second and third voltages, thereby defining a maximum feedback position at witch the maximum voltage occurs.

2. The solar system as claimed in claim 1, wherein the feedback module drives the actuator to shift the substrate to the first, second, third, and maximum feedback positions along the axis direction.

3. The solar system as claimed in claim 1, wherein the first position is between the second and third positions.

4. The solar system as claimed in claim 3, wherein the distances between the first, second and third positions are integer multiples of a unit distance.

5. The solar system as claimed in claim 4, wherein the unit distance is smaller than or the same as that of a pitch of the solar cell array and a pitch of the optical element array.

6. The solar system as claimed in claim 5, wherein the pitch of the solar cell array is the same as the pitch of the optical element array.

7. The solar system as claimed in claim 1, wherein a horizontal distance between an edge of the substrate and an edge of the optical element array adjacent and parallel to the edge of the substrate is smaller than or the same as that of a pitch of the solar cell array and a pitch of the optical element array.

8. The solar system as claimed in claim 1, wherein when the first voltage is larger than the second voltage, the substrate is negatively shifted along the axis direction by the feedback module until the sunbeams are concentrated onto the first position.

9. The solar system as claimed in claim 8, wherein the maximum feedback position is the first position when the first voltage is larger than the third voltage.

10. The solar system as claimed in claim 1, wherein when the first voltage is smaller than or the same as the second voltage, the substrate is shifted by a fourth distance positively along the axis direction by the feedback module to measure a fourth voltage of the solar cell array when the sunbeams are concentrated on a fourth position on the substrate by the optical element array, wherein a distance between the first and fourth positions is larger than that between the first and second positions.

11. The solar system as claimed in claim 1, wherein when the first voltage is smaller than or the same as the third voltage, the substrate is shifted by a fifth distance negatively along the axis direction by the feedback module to measure a fifth voltage of the solar cell array when the sunbeams are concentrated on a fifth position on the substrate by the optical element array, wherein a distance between the first and fifth positions is larger than that between the first and third positions.

12. A solar tracking method for a solar system having a solar cell array on a substrate, comprising the steps of:
(a) measuring a first voltage of the solar cell array at a first position on the substrate;
(b) shifting the substrate by a first distance positively along an axis direction;
(c) measuring a second voltage of the solar cell array at a second position on the substrate;
(d) shifting the substrate by a second distance negatively along the axis direction;
(e) measuring a third voltage of the solar cell array at a third position on the substrate;
(f) finding a maximum voltage among the first, second and third voltages;
(g) defining a maximum feedback position at witch the maximum voltage occurs; and
(h) shifting the substrate to the maximum feedback position.

13. The solar tracking method as claimed in claim 12, wherein the first, second and third distance are integer multiples of a unit distance.

14. The solar tracking method as claimed in claim 13, wherein the unit distance is smaller than or the same as that of a pitch of the solar cell array and a pitch of the optical element array.

15. The solar tracking method as claimed in claim 12, wherein a horizontal distance between an edge of the substrate and an edge of the optical element array adjacent and parallel to the edge of the substrate is smaller than or the same as that of a pitch of the solar cell array and a pitch of the optical element array.

16. The solar tracking method as claimed in claim 12, further comprising:
(c1) shifting the substrate negatively along the axis direction to the first position when the first voltage is larger than the second voltage after performing step (c) and before performing step (d).

17. The solar tracking method as claimed in claim 16, wherein the maximum feedback position is the first position when the first voltage is larger than the third voltage.

18. The solar tracking method as claimed in claim 12, wherein when the axis direction comprises an X-axis direction and a Y-axis direction, the maximum voltage comprises a maximum X-axis voltage and a maximum Y-axis voltage.

19. The solar tracking method as claimed in claim 12, further comprising:
(c2) shifting the substrate by a fourth distance positively along the axis direction; and
(c3) measuring a fourth voltage of the solar cell array at a fourth position on the substrate when the first voltage is smaller than or the same as the second voltage, wherein a distance between the first and fourth positions is larger than that between the first and second positions after performing step (c) and before performing step (d).

20. The solar tracking method as claimed in claim 12, further comprising:
(e1) shifting the substrate by a fifth distance negatively along the axis direction; and
(e2) measure a fifth voltage of the solar cell array at a fifth position on the substrate when the first voltage is smaller than or the same as the third voltage, wherein a distance between the first and fifth positions is larger than that between the first and third positions after performing step (e) and before performing step (f).
